(19) United States
(12) Patent Application Publication
(10) Pub. No.: US 2011/0297427 A1
(43) Pub. Date: Dec. 8, 2011

(54) PRINTED CIRCUIT BOARD AND A METHOD OF MANUFACTURING THE SAME

(75) Inventors: Dong Hwan Lee, Gyeongsangnam-do (KR); Dae Hyung You, Gyeongsangnam-do (KR); Sang Hyuk Son, Busan (KR)

(73) Assignee: SAMSUNG ELECTRO-MECHANICS CO., LTD., Gyunggi-do (KR)

(21) Appl. No.: 13/151,108

(22) Filed: Jun. 1, 2011

(30) Foreign Application Priority Data
Jun. 4, 2010 (KR) 10-2010-0052925

(51) Int. Cl. H05K 7/20; H05K 3/00

(52) U.S. Cl. 174/252; 29/829

(57) ABSTRACT

Disclosed herein are a printed circuit board and a method of manufacturing the same. The printed circuit board includes a metal layer divided into a plurality of regions; a build-up layer formed on at least one surface of the metal layer; and a penetrating part penetrating through the metal layer including the build-up layer and electrically separating each of the plurality of regions of the metal layer. The metal layer is configured of the plurality of regions, the ground layers and the power layers that have different functions, thereby making it possible to be thin, and the plurality of regions of the metal layer are connected through a bridge and are then penetrated through by the penetrating part, thereby making it possible to easily manufacture the printed circuit board.

### CROSS REFERENCE TO RELATED APPLICATION

This application claims the benefit of Korean Patent Application No. 10-2010-0052925, filed on Jun. 4, 2010, entitled “A Printed Circuit Board And A Method Of Manufacturing The Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, electronic products have rapidly become multifunctional and high-speed. In order to cope with such a trend, a semiconductor chip and a printed circuit board mounted with a semiconductor chip connecting the semiconductor chip to a main substrate have been also rapidly developed.

The high-speed and the high integration of the printed circuit board are requested when developing the printed circuit board. In order to meet the requirements, the printed circuit board is requested to be light and slim and have a fine pattern, excellent electrical characteristics, high reliability, high-speed signal transfer structure, or the like. Therefore, there are many demands for improvement and development of the printed circuit board.

Meanwhile, with the development of the printed circuit board, more electronic products are mounted on the printed circuit board, such that the printed circuit board generates considerable amount of heat due to the increase in the number of mounted electronic products and the density thereof. Therefore, researches on a printed circuit board including a metal core that can rapidly discharge the heat generated from embedded devices or the like have progressed.

FIG. 1 is a cross-sectional view and a perspective view of a printed circuit board 10 according to the prior art. Hereinafter, the printed circuit board 10 will be described with reference to the figure.

As shown in FIG. 1, the printed circuit board 10 according to the prior art includes a build-up layer 20 including a first build-up layer 21, a second build-up layer 22, and a third build-up layer 23, and a metal layer 30 including a first metal layer 31 and a second metal layer 32.

More specifically, the first metal layer 31 is formed on the first build-up layer 21 configured of a plurality of insulating layers and circuit layers, the second build-up layer 22 is formed on the first metal layer 31, the second metal layer 32 is formed on the second build-up layer 22, and the third build-up layer 23 is formed on the second metal layer 32.

Herein, the first metal layer 31 and the second metal layer 32 correspond to a metal core that discharges heat generated from a chip (not shown) or the like mounted on the printed circuit board 10. The first metal layer 31 and the second metal layer 32 may function as a ground layer or a power layer that supplies power, while discharging heat. For example, the first metal layer 31 may be a ground layer, and the second metal layer 32 may be a power layer.

However, in the printed circuit board 10 according to the prior art, the first metal layer 31 and the second metal layer 32 serve to perform a different function, as a ground layer and a power layer, respectively, such that in order to insulate therebetween, the metal layer 30 should be configured of two layers and the separate second build-up layer 22 should be interposed between the first metal layer 31 and the second metal layer 32. Accordingly, the printed circuit board 10 becomes thick and the manufacturing costs increase due to the interposition of the second build-up layer 22.

In addition, even though the metal layer 30 is to be configured of a single layer in order to solve the problems, the metal layer 30 should be stacked in a separate state in order to isolate between the first and second metal layers 31 and 32. Therefore, due to deviation from centers of the layers and the like, the manufacturing process is difficult and the process time and the process costs increase.

### SUMMARY OF THE INVENTION

The present invention has been made in an effort to provide a printed circuit board that configures ground layers or power layers that have different functions in a single layer to be manufactured to be thinner and to reduce manufacturing costs, and a method of manufacturing the same.

The present invention has been also made in an effort to provide a printed circuit board that has an easy and simple manufacturing process, while configuring ground layers or power layers that have different functions in a single layer, and a method of manufacturing the same.

A printed circuit board according to a preferred embodiment of the present invention includes: a metal layer divided into a plurality of regions; a build-up layer formed on at least one surface of the metal layer; and a penetrating part penetrating through the metal layer including the build-up layer and electrically separating each of the plurality of regions of the metal layer.

Herein, the plurality of regions of the metal layer are ground layers or power layers that have different functions.

Further, the metal layer is a heat sink layer made of copper.

A method of manufacturing a printed circuit board according to a preferred embodiment of the present invention includes: (A) forming a first build-up layer; (B) forming a metal layer of which a plurality of regions are connected through a bridge on the first build-up layer; and (C) electrically separating each of the plurality of regions of the metal layer by allowing a penetrating part to penetrate through the bridge of the metal layer including the first build-up layer.

At this time, the method further includes forming a second build-up layer on the metal layer between step (B) and step (C).

Further, at step (C), the penetrating part penetrates through the bridge of the metal layer including the first build-up layer and the second build-up layer.

Further, the metal layer is a heat sink layer made of copper.

Further, at step (C), the penetrating part penetrates through the bridge using a CNC drill.

Further, the plurality of regions of the metal layer are ground layers or power layers that have different functions.

### BRIEF DESCRIPTION OF THE DRAWINGS

FIG. 1 is a cross-sectional view and a perspective view of a printed circuit board according to the prior art;

FIG. 2 is a cross-sectional view and a perspective view of a printed circuit board according to a preferred embodiment of the present invention; and

FIGS. 3 to 6 are process cross-sectional views and process perspective views for explaining a method of manufacturing the printed circuit board of FIG. 2.

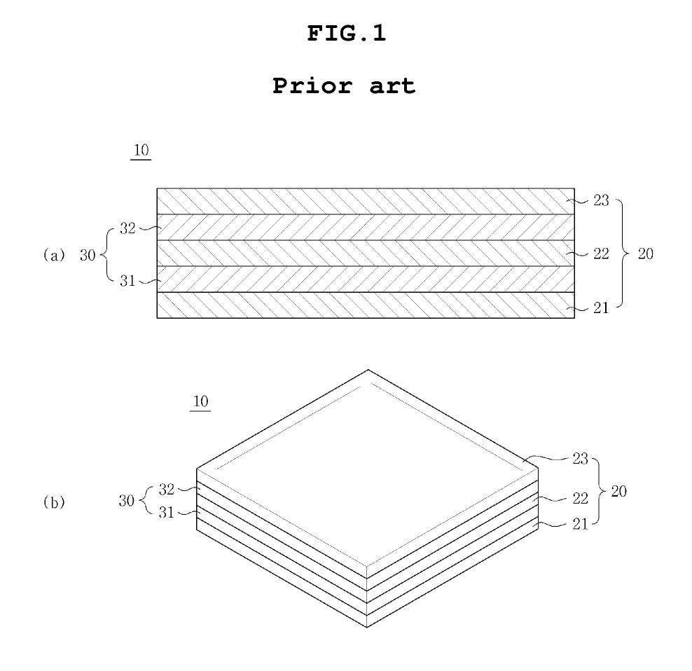

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, terms used in the specification, ‘first’, ‘second’, etc. can be used to describe various components, but the components are not to be construed as being limited to the terms. The terms are only used to differentiate one component from other components. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

Structure of Printed Circuit Board

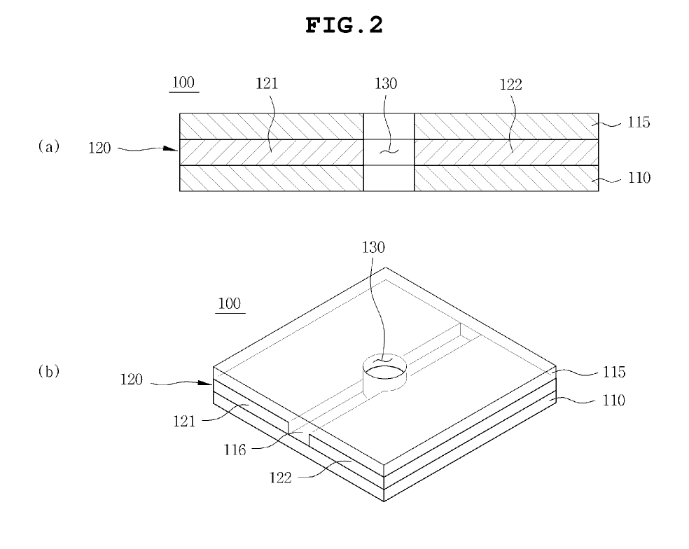

FIG. 2 is a cross-sectional view and a perspective view of a printed circuit board 100 according to a preferred embodiment of the present invention. Hereinafter, the printed circuit board 100 according to the present embodiment will be described with reference to the figure.

Meanwhile, for convenience of explanation, the upper plate, that is, a second build-up layer 115, is shown to be transparent in the perspective view of the printed circuit board 100 in the present embodiment, the present invention is not limited thereto.

As shown in FIG. 2, the printed circuit board 100 according to the present embodiment includes build-up layers 110 and 115, a metal layer 120, and a penetrating part 130, wherein the penetrating part 130 electrically separates between a plurality of regions 121 and 122 of the metal layer 120.

The build-up layers 110 and 115, which are basic members of the printed circuit board 100, may be formed on one surface or both surfaces of the metal layer 120.

Herein, although the build-up layers 110 and 115 are not specifically shown, they may include a single build-up layer circuit layer and a single build-up insulating layer or a plurality of build-up circuit layers and build-up insulating layers. The build-up insulating layer may use composite polymer resin that is generally used as an interlayer isolation material. For example, the build-up insulating layer may use a prepreg, or an epoxy resin such as Ajinomoto Build up Film (ABF), a Bismaleimide Triazine (BT) or the like. In addition, the build-up circuit layer may, for example, be made of a conductive metal such as gold, silver, copper, nickel, or the like.

Meanwhile, the build-up layers 110 and 115 on at least one surface of the metal layer 120, for example, the build-up insulating layer 116 of the second build-up layer 115 may be impregnated between the plurality of regions 121 and 122 of the metal layer 120.

The metal layer 120 is a member that contacts the build-up layers 110 and 115 to discharge heat and is divided into a plurality of regions 121 and 122.

Herein, the metal layer 120 is divided into a plurality of regions 121 and 122 and the first region 121 and the second region 122 do not contact each other so that they may be ground layers or power layers that have different functions. As a result, the metal layer 120 can be configured of a single layer. In addition, the metal layer 120 is configured of a single layer, thereby making it possible to manufacture the printed circuit board to be thinner.

Meanwhile, the metal layer 120 may be made of a conductive metal, for example, copper, so that it can be a ground layer or a power layer. In the case of copper, it has excellent thermal conductivity, such that the heat generated from chips or the like mounted on the build-up layers 110 and 115 can be effectively discharged to the outside.

In addition, the build-up insulating layer 116 is impregnated between the first region 121 and the second region 122, such that the first region 121 can be more effectively insulated from the second region 122.

Meanwhile, even though the present embodiment describes the case in which the metal layer 120 is divided into two regions 121 and 122, that is, the first region 121 and the second region 122, the present invention is not limited thereto but may be formed to have three or more regions.

The penetrating part 130 is connected to a connecting part of the metal layer 120 to separate the first region 121 and the second region 122 of the metal layer 120.

Herein, the penetrating part 130 may vertically penetrate through the connecting part of the first region 121 and the second region 122 including the build-up layers 110 and 115. Even though the penetrating part 130 is shown to be hollow in FIG. 2, the penetrating part 130 may be filled with the insulating layer or the like. Further, the cross-section shape of the penetrating part 130 is not limited to a circular shape, but may be a polygonal shape such as a triangular shape, a quadrangular shape or the like.

Meanwhile, the penetrating part 130 does not always need to be formed on both the build-up layers 110 and 115 on both surfaces of the metal layer 120, but may penetrate through only the build-up layer on one surface of the metal layer 120, for example, the second build-up layer 115.

Method of Manufacturing Printed Circuit Board

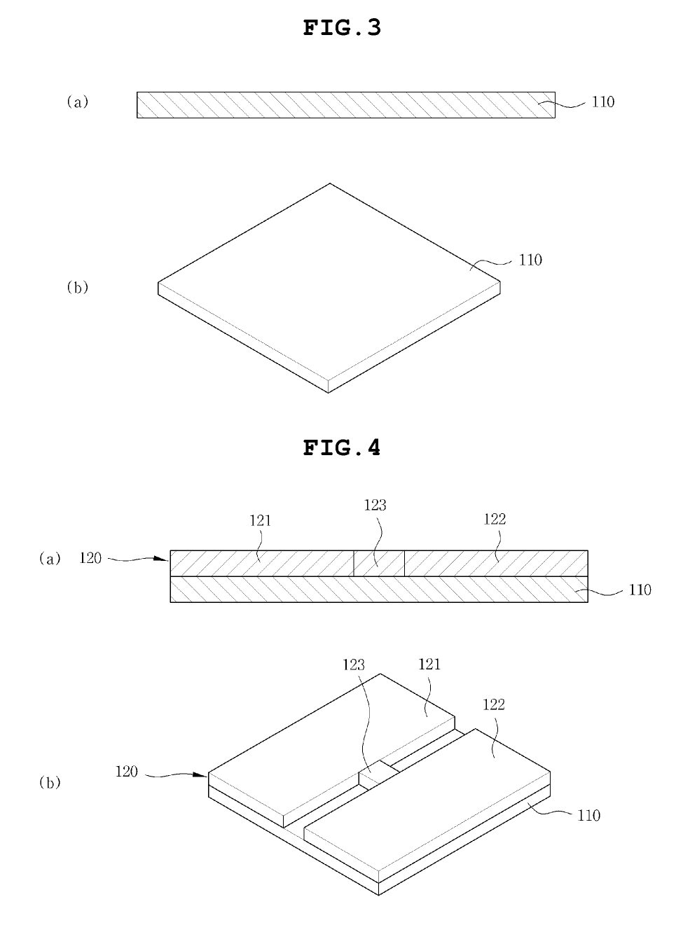

FIGS. 3 to 6 are process cross-sectional views and process perspective views for explaining a method of manufacturing the printed circuit board 100 of FIG. 2. Hereinafter, a method of manufacturing the printed circuit board 100 according to a preferred embodiment of the present invention will be described with reference to the figures.

First, as shown in FIG. 3, the first build-up layer 110 is prepared.

At this time, the first build-up layer 110 includes a singular or a plurality of build-up circuit layers and build-up insulating layers and may be formed through a general method. For example, the build-up circuit layer may be formed using a subtractive method, an additive method, a semi-additive method, a modified semi-additive method, or the like. Further, the build-up circuit layers may be connected through a via.

Then, as shown in FIG. 4, the metal layer 120 is formed on the first build-up layer 110.

At this time, the metal layer 120 may be divided into the first region 121 and the second region 122, wherein the first region 121 may be connected to the second region 122 through a bridge 123. The first region 121 is connected to the second region 122 through the bridge 123, such that when the metal layer 120 is formed on the first build-up layer 110, it is possible to stack the first region 121 and the second region 122 at one time, without stacking them separately, and to reduce the generation of eccentricity.

Meanwhile, the bridge 123 may be made of the same material as the metal layer 120, for example, copper.

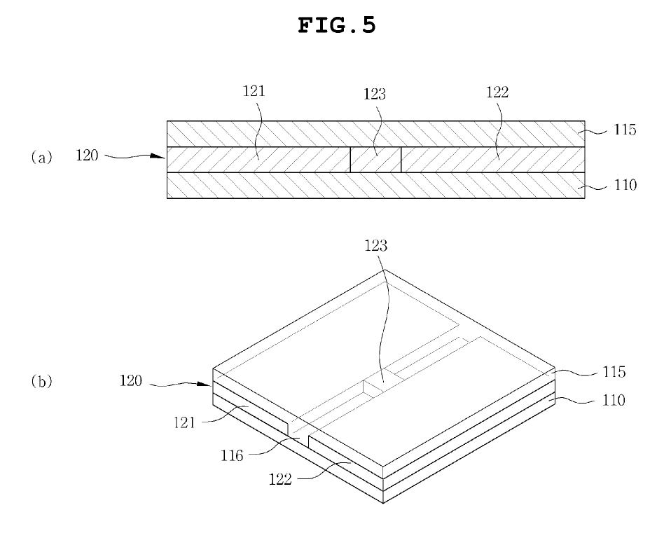

Then, as shown in FIG. 5, the second build-up layer 115 can be formed on the metal layer 120.

At this time, the second build-up layer 115 may include a singular or a plurality of build-up insulating layers and build-up circuit layers, similar to the first build-up layer 110. In addition, the second build-up layer 115 is formed on the metal layer 120 divided into the first region 121 and the second region 122, such that the build-up insulating layer 116 of the second build-up layer 115 may be impregnated in the portion between the first region 121 and the second region 122 where the bridge 123 is not formed.

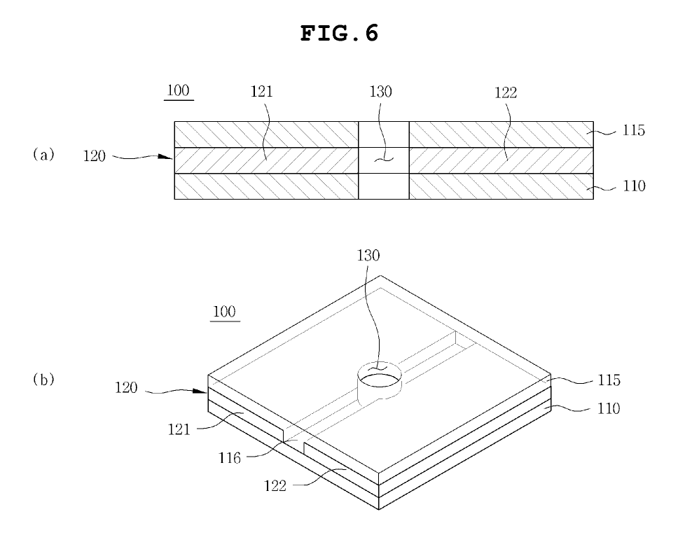

Then, as shown in FIG. 6, the penetrating part 130 penetrates through the region in which the bridge 123 of the metal layer 120 is formed.

At this time, the penetrating part 130 penetrating through the bridge 123 of the metal layer 120 is formed but the penetrating part 130 may be formed up to the build-up layers 110 and 115 on at least one surface of the metal layer 120, which are vertical to the bridge 123. The penetrating part 130 penetrates through the bridge 123, such that the first region 121 and the second region 122 of the metal layer 120 can be simply separated from each other and be electrically insulated from each other. Therefore, the first region 121 and the second region 122 can be used, for example, as a ground layer or a power layer that has a different function.

Meanwhile, the penetrating part 130 penetrating through the bridge 123 may be formed, for example, by using a CNC drill.

The printed circuit board 100 according to a preferred embodiment of the present invention in FIG. 6 is manufactured according to the manufacturing processes as described above.

With the printed circuit board and a method of manufacturing the same according to the present invention, the metal layer in a single layer is formed to have a plurality of separate regions and the plurality of regions are configured of ground layers or power layers that have different functions, thereby making it possible to manufacture the printed circuit board to be thinner and reduce manufacturing costs.

In addition, according to the present invention, the build-up process progresses while the plurality of regions of the metal layer are connected through the bridge, such that the generation of eccentricity is reduced, thereby making it possible to make the manufacturing process of the printed circuit board easy and simple.

In addition, according to the present invention, the penetrating part penetrates through the bridge after the build-up process, thereby simply insulating the plurality of regions of the metal layer from each other.

In addition, according to the present invention, the metal layer is made of copper, thereby making it possible to maintain heat sink characteristics and circuit characteristics.

Although the preferred embodiments of the present invention have been disclosed for illustrative purposes, they are for specifically explaining the present invention and thus a printed circuit board and a method of manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed circuit board, comprising:
a metal layer divided into a plurality of regions;
a build-up layer formed on at least one surface of the metal layer; and
a penetrating part penetrating through the metal layer including the build-up layer and electrically separating each of the plurality of regions of the metal layer.

2. The printed circuit board as set forth in claim 1, wherein the plurality of regions of the metal layer are ground layers or power layers that have different functions.

3. The printed circuit board as set forth in claim 1, wherein the metal layer is a heat sink layer made of copper.

4. A method of manufacturing a printed circuit board, comprising:
(A) forming a first build-up layer;
(B) forming a metal layer of which a plurality of regions are connected through a bridge on the first build-up layer; and
(C) electrically separating each of the plurality of regions of the metal layer by allowing a penetrating part to penetrate through the bridge of the metal layer including the first build-up layer.

5. The method of manufacturing a printed circuit board as set forth in claim 4, further comprising:
forming a second build-up layer on the metal layer between step (B) and step (C).

6. The method of manufacturing a printed circuit board as set forth in claim 5, wherein at step (C), the penetrating part penetrates through the bridge of the metal layer including the first build-up layer and the second build-up layer.

7. The method of manufacturing a printed circuit board as set forth in claim 4, wherein the metal layer is a heat sink layer made of copper.

8. The method of manufacturing a printed circuit board as set forth in claim 4, wherein at step (C), the penetrating part penetrates through the bridge using a CNC drill.

9. The method of manufacturing a printed circuit board as set forth in claim 4, wherein the plurality of regions of the metal layer are ground layers or power layers that have different functions.
